(19) United States
(12) Patent Application Publication
(10) Pub. No.: US 2011/0186116 A1
(43) Pub. Date: Aug. 4, 2011

(54) METHOD FOR PRODUCING A SOLAR CELL HAVING A TWO-STAGE DOPING

(75) Inventors: Jens Kruemberg, Konstanz (DE); Ihor Melnky, Konstanz (DE); Eva-Maria Holbig, Konstanz (DE); Michael Schmidt, Konstanz (DE); Steffen Keller, Konstanz (DE); Peter Fath, Konstanz (DE); Reinhold Schlosser, Muenchen (DE)

(73) Assignee: GP SOLAR GMBH, Konstanz (DE)

(21) Appl. No.: 13/055,754

(22) PCT Filed: Jul. 27, 2009
(86) PCT No.: PCT/IB2009/006367

§ 371 Date: Apr. 14, 2011

(30) Foreign Application Priority Data
Jul. 25, 2008 (DE) 10 2008 034 965.8
Oct. 22, 2008 (DE) 10 2008 052 660.6

(51) Int. Cl. H01L 31/06; H01L 31/18

(52) U.S. Cl. 136/255; 438/57; 257/E31.001

(57) ABSTRACT

Method for producing solar cells with a two-stage doping (9, 11) comprising the method steps of heavy doping (50) of at least a part of the solar cell substrate (1), of at least temporarily protecting doped areas (8), in which heavily doped areas (9) of the two-stage doping (9, 11) should be formed, from an etching medium and etching back (54; 62, 64; 72, 74) unprotected doped areas (17) of the solar cell substrate (1) by means of the etching medium, whereby, for the purpose of protecting the doped areas, sacrificial structures (7) are ap [symbol] plied (52) on the areas (8) to be protected, which are at least partly etched (54; 62, 64; 72, 74) during etching back (54; 62, 64; 72, 74) of the unprotected doped areas.

In the field of the production of solar cells one continuously strives to produce solar cells having higher conversion efficiencies. One approach for this is the usage of a two-stage doping for formation of a two-stage emitter. This way of proceeding is based on the insight that on the one hand good electrical contact can be made to a heavily or highly doped emitter for the purpose of conducting away generated current, and that on the other hand, however, a heavily or highly doped emitter is associated with losses during current generation as compared to a less heavily doped emitter due to charge carrier recombination, whereas said losses deteriorate the efficiency. Efficiency enhancement can therefore be reached by forming the emitter by means of a two-stage doping such that a heavy doping and consequently a heavily doped emitter is available in the areas to be electrically contacted, whereas in the remaining areas a weak doping, as compared to the heavily doped emitter area, is available.

In the present case, a heavily or highly doped area of an emitter should be understood as meaning an emitter area with an emitter sheet resistance of less than about 70 Ω/sq, so that it can be electrically contacted by means of industrially applied screen printing technology. As compared to this heavily doped emitter area, a weakly doped area of an emitter should be understood in the present case as meaning a doping which leads to a sheet, resistance of usually more than 70 Ω/sq. In this connection it is clear for a person skilled in the art that said value can be smaller for emitters being driven-in deeply.

A two-stage doping cannot only be advantageously used with an emitter. For example, a solar cell substrate may comprise a two-stage volume doping or a back surface field of a solar cell may be realised as two-stage doping. In general, the term ‘weak’ doping, or ‘weakly’ doped areas respectively, has always to be understood in comparison to the related heavily doped area of the same kind; in case of a weakly doped area of an emitter, consequently, in comparison to a heavily doped area of the emitter, but not in relation to a heavily doped back surface field, for example.

It must therefore be taken into account that areas with varying levels of doping can be present in the case of one solar cell, which areas can in principle in each case be embodied as two- or multi-stage doping. For example, an emitter, a back surface field or the volume doping of the solar cell substrate can be embodied as two- or multi-staged.

The sheet resistances mentioned above to delimit a heavily doped area of an emitter from a weakly doped area of an emitter can therefore not simply be transferred to other two-stage dopings. The boundary thereof between the heavily and weakly doped area can deviate from this. If one assumes, for example, a solar cell with a volume area, which is doped in two-stages, of the solar cell substrate and a two-stage emitter, the sheet resistance of the heavily doped volume area of the solar cell substrate would be very much higher than the sheet resistance of the weakly doped area of the emitter.

According to the above statements, the sheet resistances in the case of two-stage back surface fields and their relationship to one another are to be considered separately from the sheet resistances of other doped areas. Depending on the type of solar cell and the contacting technologies and materials used, the values for the sheet resistances can vary in the case of two-stage back surface fields. In the event of contacting the solar cell with conventional, industrially applied screen printing technology, sheet resistances of less than approximately 60 Ω/sq under the areas to be contacted and of more than approximately 60 Ω/sq between the areas to be contacted have proved to be effective.

Methods for producing a two-stage emitter, which is also referred to as a selective emitter, are known from the prior art, in the case of which, after a large-area, heavy emitter diffusion, the areas of the emitter to be heavily doped are masked with an etch-resistant coating, generally a polymer compound, and the unmasked areas are etched back. After the end of the etching process, the masking is removed. A heavily doped emitter area is thus present in the previously masked areas, whereas heavily doped areas of the solar cell substrate were etched away in the areas which have been etched back so that only a weak doping remains in these areas. The etch-resistant polymers or polymer compounds used in these methods as masking are indeed easy to handle in the course of the solar cell production process, but their disposal after removal of the masking is complex and as a result costly. This applies in the same way to the solvents used to remove the masking. The polymer compounds and solvents used furthermore require complex protection measures during manufacture, for example, explosion protection. The same outlay is required for the formation of other two-stage dopings, for example, of a two-stage back surface field.

The object of the present invention is therefore to provide a method by means of which a solar cell with a two-stage doping can be produced with little outlay.

This object is achieved by a method with the features of claim 1.

Advantageous further developments are the subject matter of dependent subordinate claims.

The invention is based on the concept of protecting the doped areas in which heavily doped areas of the two-stage doping should be formed from an etching medium after a heavy doping of at least a part of a solar cell substrate by applying sacrificial structures on the areas to be protected which are at least partly etched during subsequent etching back of unprotected doped areas of the solar cell substrate by means of the etching medium.

Therein, etching back should be understood as meaning etching in the case of which the etched object is not entirely removed. Therefore, only a part of the unprotected doped areas of the solar cell substrate is removed in the case of etching back. There remain unprotected areas which are doped as before, but the doping substance concentration is lower as a result of the etching back.

The sacrificial structures are materials which are attacked, i.e. etched, during etching back by a used etching medium. The manner in which the sacrificial structures are etched during etching back is irrelevant. For example, the etching of the sacrificial structures can comprise a superficial removal of material or even only a roughening of the surface or a selective etching.

The protective effect of the sacrificial structures lies in, during etching back, attacking, i.e. etching, them first and not the doped areas on which they are arranged. Depending on the selected materials for the etching medium and for the sacrificial structures and as a function of the configuration of the method according to the invention, the sacrificial structures must be formed in different forms. If the sacrificial structures are, for example, attacked to a similar degree by the etching medium used as unprotected areas of the solar cell substrate, the sacrificial structures should be formed in a greater thickness than in the case of a material selection for etching medium and sacrificial structures, in which the sacrificial structures are attacked to a significantly lesser extent by the etching medium used than the unprotected areas of the solar cell substrate. It is important to protect the areas located below the sacrificial structures from the influence of the etching medium for sufficiently long such that the desired difference in the doping substance concentration is adjusted in the protected and unprotected doped areas of the solar cell substrate, i.e. the heavily doped areas have a doping which is heavier to the desired extent than the areas of the solar cell substrate which have a weaker doping as a result of the absence of protection.

As a result of the use of sacrificial structures instead of etching barriers, the range of the materials which can be used for protection of doped areas of the solar cell substrate is significantly extended. Hence, it is possible to do without the use of maskings which are difficult to dispose of and solvents which are difficult to dispose of for the removal of the masking. Moreover, complex protective measures during manufacture, for example, explosion protection as etch-resistant maskings and associated solvents demand, are not required.

In one preferred embodiment variant of the invention, the sacrificial structures are formed from substantially inorganic materials. In other words, their content of inorganic substances is configured such that the formed sacrificial structures can be etched or dissolved by means of inorganic etching media or solvents. This can thus in principle also encompass organic substances provided that these do not require the use of inorganic solvents. The applied materials can thus, for example, contain organic components which facilitate the application of materials on the solar cell substrate. These can either remain in the ultimately formed sacrificial structure provided that the described behaviour with regard to etching media and solvents is ensured. Alternatively, they can be expelled prior to etching back in a stabilising step. For example, pastes can thus contain organic components which facilitate an application of the materials for formation of the sacrificial structures by means of printing of the paste, particularly by means of screen printing. However, these are then degasified, burnt or reduced in another manner in a tempering or sintering step prior to etching back.

Since inorganic materials are used to a large extent in semiconductor technology, in the field of solar cell production in particular silicon, the inorganic technologies required already exist and are tried-and-tested, in particular technologies for the application and removal of inorganic materials. Developed and tried-and-tested devices are also available for industrial production.

A glass is preferably provided as the sacrificial structure, for example, silicon dioxide. This can be applied in the form of a paste with organic additives, which enable screen or spray printing of this paste, on the solar cell substrate and the sacrificial structure can be formed in a subsequent sintering step.

There is a wide choice of substantially inorganic materials, for example, borax glass can be used as an alternative or in addition to silicon dioxide.

In one configuration variant of the invention, the sacrificial structures are formed from a material which has a substance which melts at low temperatures such that the sacrificial structure can be melted onto the solar cell substrate by heating. However, this must take place at as low a temperature as possible since otherwise, on the one hand, a deterioration in the doping profile in the solar cell substrate can occur, on the other hand there is the risk of introduction of contamination into the solar cell substrate, which can both have a negative effect on the level of efficiency of the manufactured solar cell. The material used should therefore be capable of being melted on at a temperature below 800° C., preferably below 600° C.

One preferred embodiment variant of the invention provides that a paste is applied as the material for the formation of the sacrificial structures. This is preferably carried out by means of a printing method which is known per se such as screen, web or spray printing and enables a simple and precise application of the sacrificial structures. Technologies already used and tried-and-tested in solar cell manufacture can furthermore be used.

In one preferred configuration variant of the invention, the sacrificial structures are treated thermally prior to the step of etching back, preferably tempered, sintered or melted. Depending on the materials used for the sacrificial structures, this has different advantages. When using pastes to apply the sacrificial structure, an organic component of the paste can be degasified, burnt or otherwise reduced, for example, as explained above, by tempering. The thermal treatment can furthermore serve to stabilise the sacrificial structures such that these are more resistant to an etching medium which is used. Furthermore, the adherence of the sacrificial structures to the areas to be protected can be formed or improved. When using a glass, for example, silicon dioxide, as a result of the thermal treatment, a closed glass body can be formed locally on the areas to be protected with a closed surface and at the same time can be connected to the solar cell substrate by means of fusing with the solar cell substrate, for example, a silicon solar cell substrate.

In principle, both an etching plasma and an etching solution can be used as the etching medium for the etching back of unprotected doped areas. An etching solution which contains nitric acid and hydrofluoric acid is preferably used. This etching solution is tried-and-tested particularly in the case of silicon solar cell substrates and also etches, for example, a sacrificial structure formed from glass which contains-silicon dioxide. The uniform removal of the solar cell substrate required is determined and ensured by conditions which can be adjusted by process technology such as temperature, concentration, flow rate and composition as well as water content.

One configuration variant of the invention provides that etching back is terminated before the sacrificial structures are entirely etched off at least at points. This prevents areas located below the sacrificial structures from being attacked. The remaining sacrificial structures are thus advantageously removed in a subsequent method step. In the case of sacrificial structures which contain silicon dioxide, this can, for example, be carried out with the help of a hydrofluoric acid solution. In one preferred configuration variant, remaining sacrificial structure residues which contain glass are removed with an etching solution which contains 1% to 10% hydrofluoric acid. The sacrificial structure residues are subjected to such an etching solution for a period in the range between 1 and 10 minutes, wherein the etching solution is at a temperature in the range between 20 and 80° C. Such a further etching step for removal of the remaining sacrificial structure residues can be easily integrated into an automatic production line, which is often referred to as inline capability, and is tried-and-tested particularly in the case of silicon solar cell substrates and sacrificial structures which contain glass.

In a different configuration variant of the invention, the sacrificial structures are entirely removed during etching back. Since the etching medium only reaches the areas to be heavily doped when the sacrificial structures have already been removed, a two-stage doping nevertheless takes place since the unprotected areas were already exposed to the etching medium from the very start and are therefore etched back to a greater extent. A two-stage doping is thus also apparent here. The separate method step of removal of the sacrificial structure residues is, however, advantageously omitted.

One particularly preferred embodiment variant of the invention provides that, for the purpose of etching back, at least in unprotected doped areas of the solar cell substrate, a porous layer is formed from the material of the solar cell substrate and is subsequently removed. The porous layer is preferably formed by etching, particularly preferably by wet chemical etching of at least parts of the solar cell substrate. If, for example, a solar cell substrate composed of silicon is used, porous silicon is accordingly formed at least on the later high-ohm areas of a two-stage doping, therefore on those areas which are not protected by sacrificial structures. As described, this is preferably carried out by wet chemical etching. The porous silicon is therefore formed from the silicon material of the solar cell substrate.

The formation of a porous layer and subsequent etching, i.e. removal, of the same enables a more homogeneous etching back of the unprotected doped areas. For example, if an emitter is embodied as two-stage doping, this leads to a higher quality emitter which ultimately makes possible solar cells with higher degrees of efficiency. The possibility of more homogeneous etching is advantageous particularly in the case of multi-crystalline solar cell substrates since in this case a plurality of etching solutions used have a stronger etching effect on the grain boundaries between the grains of the solar cell substrate than the grains themselves and to a certain extent grains with different orientations are also etched to a varying degree.

The porous layer is preferably removed by means of an alkaline etching solution, preferably with an etching solution which contains potassium hydroxide, sodium hydroxide and/or ammonium hydroxide. It has been shown that a particularly homogeneous etching back, in particular of silicon solar cell substrates, is possible with these etching solutions. Therein, the etching back of porous layers with the cited etching solutions delivers more homogeneous etching results than the use of the cited etching solutions without prior formation of a porous layer.

If the etching back is carried out together with the formation of a porous layer and should the sacrificial structures be entirely removed during etching back, one preferred configuration variant of the invention provides that the sacrificial structure residues are removed together with the porous layer. A separate method step for removal of the sacrificial structure residues is thus omitted.

In the case of one preferred configuration variant of the invention, an emitter or a back surface field is embodied as two-stage doping. Such a two-stage emitter is often referred to as a selective emitter, a two-stage back surface field as a back surface field.

It has been shown that the invention can be advantageously used in the case of solar cell substrates composed of silicon which are already currently used on a large scale in industrial manufacture. One embodiment variant correspondingly provides that a solar cell substrate composed of silicon is used, preferably a crystalline and particularly preferably a multi-crystalline silicon solar cell substrate.

If solar cell substrates composed of silicon are used, it has proved to be expedient to use materials which contain glass in the form of a silicon compound for formation of the sacrificial structures. For example, materials which contain silicon dioxide or materials which contain silicate glass can be used. For the purpose of etching back of sacrificial structures, the 1% to 10% strength hydrofluoric acid solution described above and the further etching step also described above for removal of the sacrificial structure residues has proved to be particularly expedient in this case. It has furthermore been shown that a porous silicon layer can be easily removed with the alkaline etching solutions mentioned above.

A solar cell with a degree of efficiency which is typical of solar cells with two-stage doping, in particular a two-stage emitter, can be produced with little outlay with the method according to the invention. In particular, solar cells with a two-stage emitter and/or a two-stage back surface field can be produced with little outlay.

The invention is explained in greater detail below with reference to figures. Where it is expedient, elements with an identical effect in this case are provided with the same reference numbers. Therein:

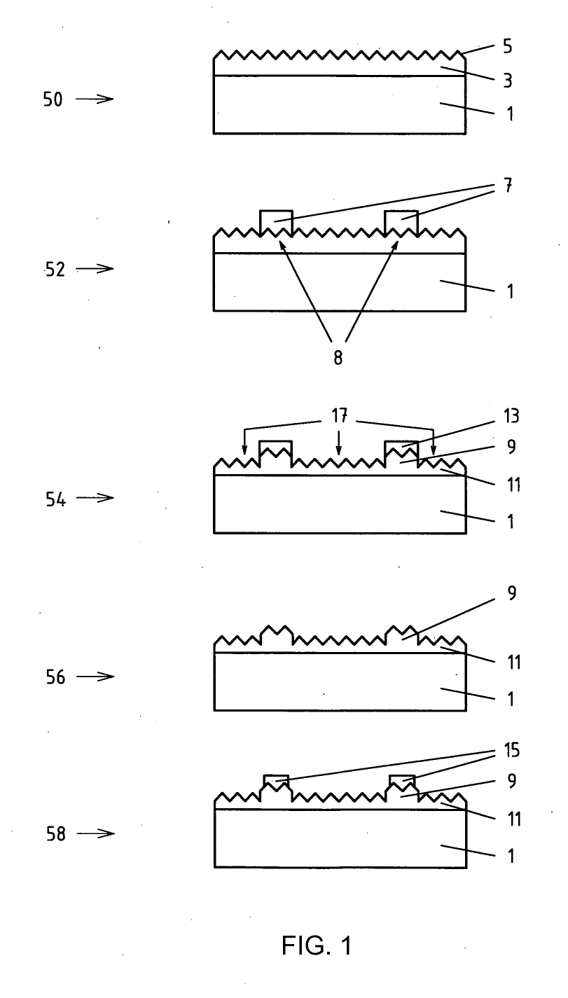

FIG. 1: shows a schematic representation of a first exemplary embodiment of the method according to the invention.

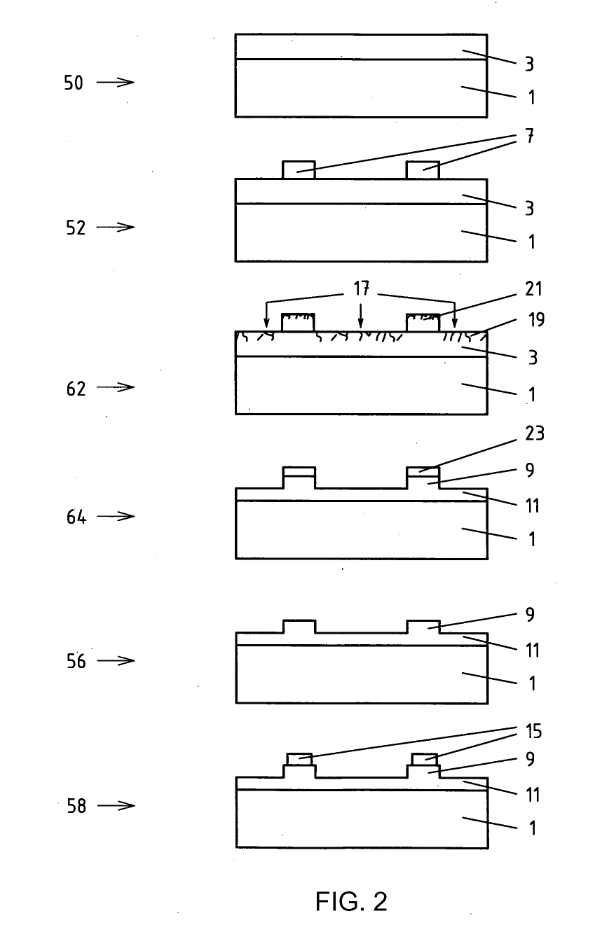

FIG. 2: shows a second exemplary embodiment of the method according to the invention, in which a porous layer is formed, in a schematic representation.

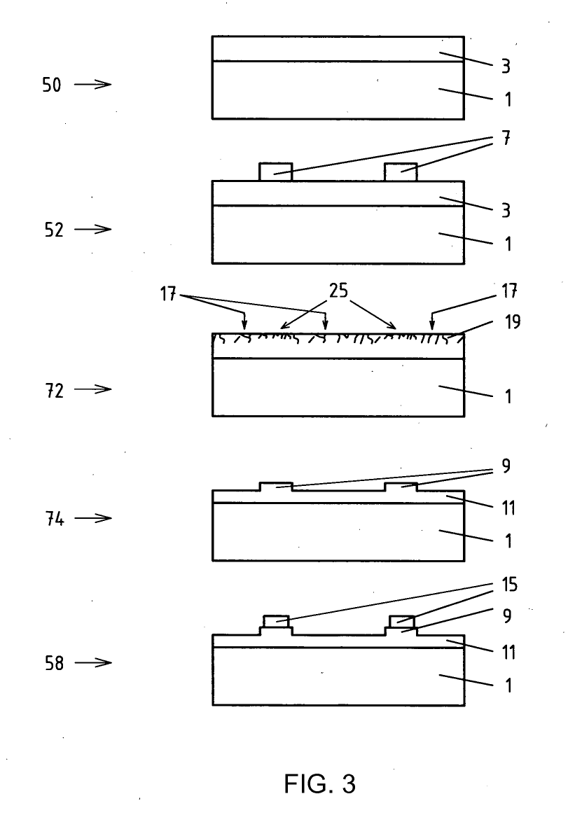

FIG. 3: shows a schematic representation of a third exemplary embodiment of the method according to the invention, in which, in turn, a porous layer is formed.

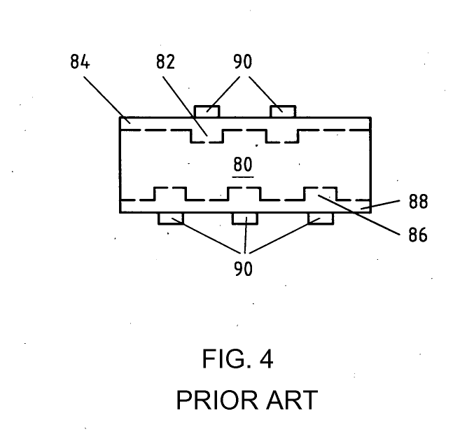

FIG. 4: shows a solar cell with two-stage dopings according to the prior art in a schematic representation.

FIG. 1 shows in a schematic representation a first exemplary embodiment of the method according to the invention. The starting point for this is a solar cell substrate 1, which is provided at its front side with a texturing 5. Therein, the front side is the large-surface side of solar cell substrate 1, which is exposed to incident light when using the solar cell. Such a texturing 5 increases the degree of efficiency as a result of a reduction in the reflection of the incident light on the surface of the finished solar cell, but is not absolutely essential. It illustrates in the present case however that the method according to the invention can be used, among other things, on textured solar cell substrates. The invention is indeed explained in the present case with reference to solar cells which are light-sensitive on one side, so-called monofacial cells, but it can clearly be equally used in the production of bifacial cells which are light-sensitive on both sides.

In accordance with the method according to the invention, in the exemplary embodiment of FIG. 1, the front side of the solar cell substrate is firstly heavily doped 50 so that a doped area 3 is formed. Such a heavy doping can, for example, be carried out by inwards diffusion of a doping substance from the gas phase, in particular a POCl₃— or a BBr₃ diffusion. In principle, however, any other doping technology which is known per se can also be used.

Moreover, sacrificial structures 7 are applied and sintered 52 on areas 8 to be protected. This can be carried out, for example, by screen printing of a paste which contains glass, in particular a paste which contains silicon dioxide, which is subsequently sintered in order to expel organic solvents and apply a glass structure onto the solar cell substrate, when necessary this glass layer can also be melted onto solar cell substrate 1.

Applied sacrificial structures 7 cover areas 8 to be protected and thus prevent an etching medium from coming into contact with said areas 8 to be protected. Therein, said areas 8 to be protected are those areas in which heavily doped areas of a two-stage doping should be formed.

Unprotected doped areas 17 are subsequently etched back 54. As can be inferred from the representation from FIG. 1, however, not only unprotected doped areas 17 are etched back, rather sacrificial structures 7 also experience a removal of material so that only sacrificial structure residues 13 remain from these. The areas located under sacrificial structures 7 and protected by them do not, however, experience any removal of material. As a result, the heavy doping initially formed is still present there and forms highly doped area 9 of the two-stage doping. As a result of the etching back, the doping substance concentration is, however, lower in unprotected doped areas 17 so that weakly doped areas 11 of the two-stage doping are present here.

Solar cell substrate 1 from FIG. 1 could, for example, be a silicon solar cell substrate in which sacrificial structures composed of silicon dioxide were formed. In this example, etching back was carried out using a silicon-etching solution and could, for example, advantageously be carried out using an etching solution which contains nitric acid and hydrofluoric acid. This would also remove the sacrificial structures formed from silicon dioxide as represented in FIG. 1. The amount of material which is to be removed from the unprotected areas, is based on the desired doping profile. In practice, an etching removal of approximately 10 to 200 nm has proved to be expedient.

After etching back 54 of the unprotected doped areas, sacrificial structure residues 13 are removed 56 in the exemplary embodiment of FIG. 1. This can be carried out, among other things, with a solution which contains hydrofluoric acid in the example of a silicon solar cell substrate described in the previous paragraph. A 1% to 10% strength hydrofluoric acid solution to which at least the sacrificial structures are exposed for approximately 1 to 10 minutes at a temperature of approximately 20 to 80° C. has proved to be expedient for this purpose. The entire solar cell substrate can also be exposed to this solution without disproportionate impairment of the heavy, new and also the weakly doped areas 11 of the two-stage doping. When using the solution which contains hydrofluoric acid, the further method step of removal 56 of sacrificial structure residues 13 can be easily integrated into production lines. The so-called inline capability of this further etching step is thus provided.

According to the representation of FIG. 1, contacts 15 are furthermore applied 58 on heavily doped areas 9 of the two-stage doping which is formed from heavily doped areas 9 and weakly doped areas 11. Prior to application 58 of contacts 15, additional surface treatment steps can obviously be carried out. For example, a passivation of two-stage doping 9, 11 or in the case of corresponding formation of selective emitter 9, 11 can be carried out by means of a passivation layer and/or an anti-reflection coating can be applied. For example, a silicon dioxide layer could be considered as a passivation layer, an anti-reflection coating could, for example, be achieved by means of a silicon nitrate deposition.

Contacts 15 can, for example, be applied in a manner known per se by printing on pastes which contain metal. For this purpose, in principle all conventional printing methods are possible, in particular screen, stamp or spray printing. In principle, contacts 15 can also be applied in a different manner, for example, by vapour deposition, but this is generally associated with increased production outlay.

FIG. 2 illustrates in a schematic representation a further exemplary embodiment of the method according to the invention. In turn, a solar call substrate 1 is firstly heavily doped 50 and as a result a doped area 3 is formed. In contrast to the representation from FIG. 1, however, a solar cell substrate 1 without texturing is used here. Such texturing could, however, be easily provided.

Moreover, in turn, sacrificial structures 7 are firstly applied 52 on the solar cell substrate and, where necessary, treated thermally, in particular sintered 52.

For the purpose of etching back unprotected doped areas 17, in this exemplary embodiment, a porous layer 19 is firstly formed 62 from solar cell substrate material. This can, for example, be carried out by etching of said areas 17. A wet chemical etching solution into which the solar cell substrate is at least partially dipped is preferably used for formation of porous layer 19 composed of solar cell substrate material. In the case shown from FIG. 2, the upper side of the solar cell substrate was exposed to such an etching solution. As a result, porous layer 19 was formed in unprotected doped areas 17. However, in the present exemplary embodiment, sacrificial structures 7 were also attacked by this wet chemical etching solution for formation of porous layer 19. This results in etching damage 21 on sacrificial structures 7.

The type of said etching damage 21 to sacrificial structures depends on the material selection for the sacrificial structures and on the composition of the etching solution formation of porous layer 19. For example, a uniform, large-area removal of sacrificial structures 7 can take place, while porous layers 19 are formed in unprotected doped areas 17 of solar cell substrate 1. It is also conceivable that the etching solution used forms porous layers both in unprotected doped areas 17 and etching damage 21 to the sacrificial structures are of a porous nature. This would in particular be the case if sacrificial structures 7 are formed from the same material as solar cell substrate 1. The etching speed on sacrificial structures 7 and unprotected doped areas 17, which can differ from one another, also depends on the selection of material.

Moreover, porous layer 19 is removed 64. In the exemplary embodiment shown from FIG. 2, a removal on the sacrificial structures simultaneously takes place such that only sacrificial structure residues 23 remain. Heavily doped areas 9 are still present under said sacrificial structure residues 23 as a result of the protection by sacrificial structures 7. However, in turn, only a weak doping is still present in unprotected doped areas 17 as a result of the material removal such that resultant weakly doped areas 11, together with heavily doped areas 9, form the desired two-stage doping.

In an analogous manner to the exemplary embodiment from FIG. 1, sacrificial structure residues 23 are furthermore removed 56 with the help of a further etching step. As described above, this can furthermore be followed by additional known method steps, for example, the application of a surface-passivation layer or of an anti-reflection coating. Moreover, in turn, contacts 15 are applied 58 onto heavily doped areas 9 of two-stage doping 9, 11.

FIG. 3 illustrates a further exemplary embodiment of the method according to the invention. The starting point is once again a solar cell substrate 1, without texturing, which, however, can be easily provided. In turn, solar cell substrate 1 is firstly heavily doped 50 on the front side. In all the exemplary embodiments, a restriction of the heavy doping to a partial surface of solar cell substrate 1 is not absolutely necessary. In principle, heavily doped area 3 can also extend across the entire surface of the solar cell substrate. In this case, however, it would have to be overcompensated or partially removed at a later time at suitable points by means of an inwards diffusion of doping substance of the opposite type.

In a similar manner to the cases of the exemplary embodiments in FIGS. 2 and 3, sacrificial structures 7 are furthermore applied on solar cell substrate 1. Furthermore, in turn, a porous layer 19 is formed 72 for the purpose of etching back of unprotected doped areas 17. Therein, the material selection is made in the exemplary embodiment shown such that the etching medium used to form porous layer 19, in particular an etching solution, etches sacrificial structures 7 over a large area so that these are removed during the formation of porous layer 19. In the case of a solar cell substrate 1 composed of silicon, this could be achieved, for example, by using silicon dioxide as the sacrificial structure and using an etching solution which contains hydrofluoric acid for formation of porous layer 19.

In the case described, the etching duration and the thickness of sacrificial structures 7 thus determine whether, on termination of the etching procedure for formation 72 of porous layer 19, residues of sacrificial structures 7 are still present or not. In the exemplary embodiment shown in FIG. 3, this is not the case. Sacrificial structures 7 were entirely removed by the etching medium used for formation 72 of porous layer 19. As a result, areas 25 previously protected by sacrificial structures 7 have been etched. In other words, a porous layer was formed here which, however, is significantly thinner than porous layer 19 in unprotected doped areas 17.

As a result; etched, previously protected doped areas 25 are also removed in the course of subsequent removal 74 of porous layer 19. Since these are, however, significantly thinner than porous layers 19 in unprotected doped areas 17, a smaller removal of material takes place here, which is ultimately due to the fact that etching media, in particular etching solutions, are used which etch porous layers 19, 25 faster than areas in which solar cell substrate 1 is still solidly present. Alkaline etching solutions, in particular those which contain potassium hydroxide, sodium hydroxide and/or ammonium hydroxide, are tried-and-tested as such etching solutions, particularly in the case of silicon solar cell substrates.

As a result, there thus remain in the exemplary embodiment from FIG. 3 heavily doped areas 9 where, prior to removal of the porous layer, etched, previously protected doped areas 25 were present. However, after removal of the porous layer, only weakly doped areas 11, which, together with heavily doped areas 9, form the desired two-stage doping, are still present in unprotected doped areas 17 in which a comparatively thick porous layer was formed.

Moreover, as already explained above, further method steps which are known per se can be added for improvement of the degree of efficiency, in particular a passivation of the surface or the formation of an anti-reflection coating. Contacts 15 are furthermore applied 58 in an analogous manner to the exemplary embodiments of FIGS. 1 and 2.

The solar cell substrate is otherwise processed further in a manner which is known per se to form a solar cell. This equally applies to the exemplary embodiments from FIGS. 1 and 2, which also do not reflect the solar cell manufacture process in its entirety. The further method steps, for example, for formation of a backward contact, are, however, known to the person skilled in the art, so it is not necessary to describe them at this point.

The method according to the invention can be advantageously used for the manufacture of solar cells with selective emitters or two-stage back surface fields.

FIG. 4 shows a solar cell 80 according to the prior art, which has both a selective emitter as well as a two-stage back surface field. Therein, selective emitter 82, 84 is formed from heavily doped emitter areas 82 and weakly doped emitter areas 84. In a similar manner, two-stage back surface field 86, 88 is formed from heavily doped areas 86 of the back surface field and weakly doped areas 88 of the back surface field. Respective heavily doped areas 82, 86 are provided with contacts 90.

### LIST OF REFERENCE NUMBERS

1 Solar cell substrate
3 Doped area
5 Texturing
7 Sacrificial structures
8 Areas to be protected
9 Heavily doped area of the two-stage doping
11 Weakly doped area of the two-stage doping
13 Sacrificial structure residue
15 Contacts
17 Unprotected doped areas
19 Porous layer composed of solar cell substrate material
21 Etching damage to sacrificial structure
23 Sacrificial structure residues
25 Etched, previously protected doped areas
50 Heavy doping
52 Application and sintering of sacrificial structures
54 Etching back unprotected, doped areas
56 Removing sacrificial structure residues
58 Applying contacts
62 Forming porous layer
64 Removing porous layer
72 Forming porous layer
74 Removing porous layer
80 Solar cell
82 Heavily doped emitter area
84 Weakly doped emitter area
86 Heavily doped area of the back surface field
88 Weakly doped area of the back surface field
90 Contacts

1-16. (canceled)

17. A method for producing a solar cell with two-stage doping the method which comprises the following steps:
heavily doping at least a part of a solar cell substrate;
defining doped areas of the substrate in which heavily doped areas of the two-stage doping shall be formed;
at least temporarily protecting the doped areas, in which heavily doped areas of the two-stage doping shall be formed, against an etching medium, by applying sacrificial structures thereon, and leaving unprotected doped areas on the solar cell substrate;
etching back the unprotected doped areas and at least partly etching the sacrificial structures during etching back of the unprotected doped areas.

18. The method according to claim 17, which comprises forming the sacrificial structures from substantially inorganic materials.

19. The method according to claim 18, wherein the sacrificial structures are formed of glass.

20. The method according to claim 17, which comprises forming the sacrificial structures from a material having at least one substance selected from the group consisting of silicon dioxide and borax glass.

21. The method according to claim 17, which comprises forming the sacrificial structures from a material having a substance that melts at temperatures below 800° C.

22. The method according to claim 21, wherein the substance melts at a temperature below 600° C.

23. The method according to claim 17, which comprises applying a paste of the material for forming the sacrificial structures.

24. The method according to claim 23, which comprises applying the paste by way of a printing method.

25. The method according to claim 17, which further comprises thermally treating the sacrificial structures prior to the step of etching back.

26. The method according to claim 25, wherein the step of thermally treating comprises a process selected from the group consisting of tempering, sintering, and melting.

27. The method according to claim 17, wherein the etching medium is an etching solution containing nitric acid and hydrofluoric acid.

28. The method according to claim 17, which comprises terminating the step of etching back before the sacrificial structures are entirely etched off, at least at points.

29. The method according to claim 28, which comprises removing sacrificial structure residues that remain after etching back in a further etching step.

30. The method according to claim 29, wherein the further etching step employs an etching solution with hydrofluoric acid.

31. The method according to claim 17, wherein the step of etching back comprises etching the sacrificial structures away entirely.

32. The method according to claim 17, which comprises, for the purpose of etching back, forming a porous layer, at least in unprotected doped areas of the solar cell substrate, from the material of the solar cell substrate, and subsequently removing the porous layer.

33. The method according to claim 32, which comprises forming the porous layer by etching.

34. The method according to claim 32, which comprises forming the porous layer by wet chemical etching.

35. The method according to claim 32, which comprises removing sacrificial structure residues together with the porous layer.

36. The method according to claim 32, which comprises etching the porous layer away with an alkaline etching solution.

37. The method according to claim 36, wherein the alkaline etching solution contains at least one substance selected from the group consisting of potassium hydroxide, sodium hydroxide, and ammonium hydroxide.

38. The method according to claim 17, which comprises providing a solar cell substrate composed of silicon.

39. The method according to claim 38, wherein the solar cell substrate is composed of crystalline silicon.

40. The method according to claim 38, wherein the solar cell substrate is composed of multi-crystalline silicon.

41. The method according to claim 17, wherein an emitter or a back surface field is embodied as two-stage doping.

42. A solar cell produced with a method according to claim 17.
